(19) United States
(12) Patent Application Publication
(10) Pub. No.: US 2016/0297106 A1
(43) Pub. Date: Oct. 13, 2016

(54) APPARATUS AND METHOD FOR MANUFACTURING PREPREG

(71) Applicants: Mitsubishi Gas Chemical Company, Inc., Tokyo (JP); MGC Electrotechno Co., Ltd., Fukushima (JP)

(72) Inventors: Masanobu SOGAME, Tokyo (JP); Takeshi NOBUKUNI, Fukushima (JP); Hiroyuki MATSUMOTO, Fukushima (JP); Fumihiko YASHIMA, Fukushima (JP); Mitsunori KUBOKI, Fukushima (JP)

(73) Assignees: MITSUBISHI GAS CHEMICAL COMPANY, INC., Tokyo (JP); MGC ELECTROTECHNO CO., LTD, Fukushima (JP)

(21) Appl. No.: 15/038,598

(22) PCT Filed: Dec. 3, 2014
(86) PCT No.: PCT/JP2014/082008

§ 371 Date: May 23, 2016

(30) Foreign Application Priority Data
Dec. 11, 2013 (JP) 2013-256462

(51) Int. Cl. B29B 15/12; C08J 5/24; C08J 5/04; H05K 1/03

(52) U.S. Cl. CPC B29B 15/125; H05K 1/0366; C08J 5/24; C08J 5/043; C08J 5/046; B29K 2309/08

(57) ABSTRACT

In the manufacture of prepreg using various types of resin varnish having different properties, prepreg having good appearance and desired properties is manufactured without decreasing productivity. A prepreg manufacturing apparatus is able to perform, in a base material feeding path, immersing a base material in resin varnish in a tray, scraping off the excess resin varnish on the base material with scraping rollers which are provided above the tray, and thereafter drying the base material with a drying device. The prepreg manufacturing apparatus is configured such that, on the base material feeding path, the distance from the liquid surface of the resin varnish in the tray to the scraping rollers and the distance from the scraping rollers to the drying device are adjustable.

### TECHNICAL FIELD

The present invention relates to an apparatus and method for manufacturing prepreg which is used as a material for a metal foil-clad laminate or a printed circuit board.

### BACKGROUND ART

Prepreg is one of the materials for printed circuit boards and metal foil-clad laminates which are used for semiconductor plastic packaging used in electronic devices, communication equipment, personal computers, etc.

Prepreg is usually manufactured by an apparatus having a base material feeding path for continuously feeding a base material. In such prepreg manufacturing apparatus, prepreg is manufactured by the process performed on the base material feeding path, which includes immersing the base material in resin varnish in a tray, scraping off excess resin on the base material with a scraping jig, and then drying the base material with a drying device. In this manufacturing apparatus, the respective positions of the tray for storing the resin varnish, the resin varnish scraping jig, and the drying device are fixed and unchangeable on the base material feeding path. There has been a continuing demand for such prepreg manufacturing apparatuses to perform the application of resin varnish properly so as to manufacture prepreg having good appearance.

### CITATION LIST

### Patent Document

Patent Document 1: JPS58-094423 A

### SUMMARY

### Technical Problem

In the meantime, semiconductor devices, which are widely used in electronic devices, communication equipment, personal computers, etc., have recently been achieving higher integration, more advanced functionality and packaging with higher density at an increasingly accelerated pace, and various properties and higher reliability have been increasingly demanded more than ever before for the printed wiring boards and metal foil-clad laminates for use in semiconductor plastic packaging. Along with such demand, various properties have also been demanded for prepreg used as the material of the printed wiring boards and metal foil-clad laminates.

In order to obtain various properties of the prepreg, a variety of types of resin varnish have been used in recent times. Due to such use, there have been some cases in which good appearance cannot be obtained by the conventional manufacturing apparatuses. For example, when resin varnish which includes a large amount of filler is used, dripping will occur from the time of impregnating the base material with the resin varnish in a tray to the time of scraping off the resin varnish with the scraping jig, and the base material is likely to have unevenness on its surface, so that prepreg having good appearance is difficult to obtain.

In such a case, increasing the speed of feeding the base material may be one way to suppress dripping; however, this also causes a decrease of the time taken for the base material to pass through the drying device and the semi-cured state of the resulting prepreg may be insufficient, so that prepreg having the desired properties cannot be obtained.

On the other hand, if, for example, resin varnish having high viscosity is used, the time from the impregnation of the base material with the resin varnish in a tray to the time of scraping off the resin varnish with a scraping jig is too short for the resin varnish to sufficiently spread over the surface of the base material, and this may cause the resulting prepreg not to have good appearance.

In such a case, it may be possible to decrease the speed of feeding the base material so as to ensure the time for the resin varnish to spread over the surface of the base material; however, this leads to a decrease in productivity.

The present invention has been made in view of the above circumstances. An object of the present invention is to manufacture prepreg having good appearance and desired properties without decreasing the productivity in the manufacture of prepreg using various types of resin varnish having different properties.

### Solution to Problem

The inventors of the present invention have found that the above-described object can be achieved by configuring both the position of a tray for storing resin varnish and the position of a scraping jig for scraping off the excess resin varnish to be adjustable, thereby completing the present invention.

That is, the present invention includes an apparatus for manufacturing a prepreg, wherein, in a base material feeding path, the base material is immersed in resin varnish in a tray, excess resin varnish on the base material is scraped off using a scraping jig provided above the tray, and the base material is then dried with a drying device, and wherein the apparatus is configured such that respective distances on the base material feeding path from a liquid surface of the resin varnish in the tray to the scraping jig and from the scraping jig to the drying device are adjustable.

The above prepreg manufacturing apparatus may have a scraping jig lifting device that moves the scraping jig up and down along the base material feeding path and a tray lifting device that moves the tray up and down.

The above prepreg manufacturing apparatus may further have an adjustment mechanism that adjusts the distance between the scraping jig and an impregnation roller that turns up the base material in the resin varnish in the tray.

The impregnation roller may be linked with a supporting mechanism of the scraping jig via a connection member so as to be moveable together with the scraping jig, and the length of the connection member may be changeable.

The connection member may be selectable from among a plurality of connection members having different lengths.

The scraping jig lifting device may be able to move the scraping jig to respective positions in contact and not in contact with the resin varnish in the tray.

Another aspect of the present invention includes a method for manufacturing a prepreg, wherein, in a base material feeding path, the base material is immersed in resin varnish in a tray, excess resin varnish on the base material is scraped off using a scraping jig provided above the tray, and the base material is then dried with a drying device, the method including a step of adjusting at least one of the distance from a liquid surface of the resin varnish in the tray to the scraping jig on the base material feeding path or the distance from the scraping jig to the drying device according to the type of resin varnish.

The above step may include at least one of a step of moving the scraping jig up and down or a step of moving the tray up and down.

The above method for manufacturing a prepreg may further include a step of adjusting the distance between the scraping jig and an impregnation roller for turning up the base material in the resin varnish in the tray.

The step of moving the scraping jig up and down may include a step of moving the scraping jig to a position in contact with the resin varnish in the tray.

### Advantageous Effects of Invention

According to the prepreg manufacturing apparatus and method of the present invention, it is possible to manufacture prepreg having desired properties and excellent appearance without decreasing productivity.

### BRIEF DESCRIPTION OF DRAWINGS

FIG. 1 is an illustration schematically showing the configuration of a prepreg manufacturing apparatus when viewed from a side.

FIG. 2 is an illustration schematically showing the configuration of a prepreg manufacturing apparatus when viewed from the front.

FIG. 3 is an illustration of a prepreg manufacturing apparatus when a distance D1 is lengthened.

FIG. 4 is an illustration of a prepreg manufacturing apparatus when a distance D1 is shortened.

FIG. 5 is an illustration of a prepreg manufacturing apparatus when scraping rollers are in contact with resin varnish.

### DESCRIPTION OF EMBODIMENTS

Hereinafter, embodiments of the present invention will be described with reference to the attached drawings. It should be noted that the same elements will be given the same reference signs and any repetitive description will be omitted. It should also be noted that, unless otherwise specified, the positional relationships, such as up-and-down and left-to-right relationships, are based on those shown in the drawings. In addition, various dimensional ratios shown in the drawings are not limited to those in the drawings. The embodiments described below are just examples for explaining the present invention and the present invention is not limited to those embodiments.

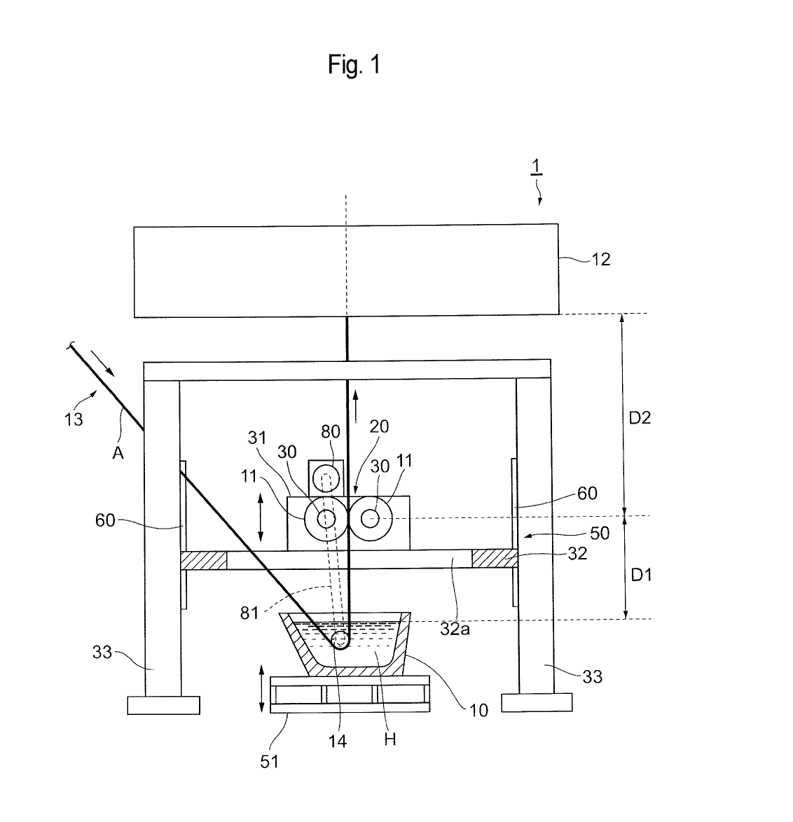

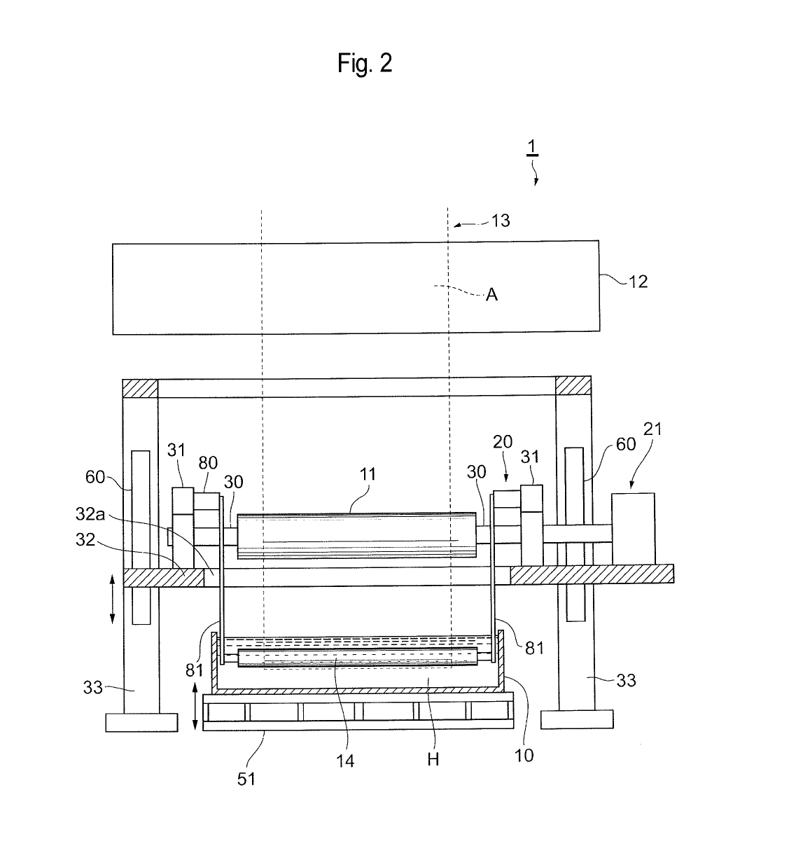

FIG. 1 is an illustration showing the schematic configuration of a prepreg manufacturing apparatus 1 when viewed from a side, while FIG. 2 is an illustration showing the schematic configuration of the prepreg manufacturing apparatus 1 when viewed from the front. For example, the prepreg manufacturing apparatus 1 may include: a tray (container) 10 for storing resin varnish H to immerse a base material A with the resin varnish H; a pair of scraping rollers 11 which are provided above the tray 10 and serve as a scraping jig for scraping off the excess resin varnish H on the surface of the base material A; and a drying device 12 for drying the base material A, and these are arranged along a base material feeding path 13 in this order from upstream to downstream.

An impregnation roller 14 that turns up the base material A is provided within the tray 10. The pair of scraping rollers 11 is provided vertically above the impregnation roller 14. The pair of scraping rollers 11 is able to scrape off the excess resin varnish H on the opposite surfaces of the base material A by contacting such surfaces of the base material A while allowing the base material A to pass between the rollers 11. Each of the scraping rollers 11 is provided with a blade (not shown in the drawings) for removing the resin varnish H adhered to the scraping roller 11. The drying device 12 is able to dry the resin varnish H on the surface of the base material A, for example, by allowing the base material A to pass through a drying chamber having a predetermined length and capable of supplying radiation heat or hot air.

The prepreg manufacturing apparatus 1 also has a roller supporting device 20 that supports the scraping rollers 11 and a roller driving device 21 that drives and rotates the scraping rollers 11. The roller supporting device 20 may include, for example, a supporting mechanism 31 which is provided on the opposite sides of the rotating shaft 30 of each scraping roller 11 so as to rotatably support the opposite ends of the rotating shaft 30, a supporting table 32 on which the above supporting mechanism 31 is placed and supported, and four columns 33 that support the supporting table 32. The supporting table 32 may have, for example, an opening 32a which is larger than the tray 10 at a position that faces the scraping rollers 11, so as to allow the tray 10 to pass through the opening 32a in an up and down manner.

The roller driving device 21 may be disposed, for example, on the supporting table 32. The roller driving device 21 can rotate the two scraping rollers 11 in opposite directions, for example, by transferring the motive power of a driving motor to the respective rotating shafts 30 of the scraping rollers 11 via a gear mechanism.

The prepreg manufacturing apparatus 1 further has a scraping roller lifting device 50 that moves the scraping rollers 11 up and down along the base material feeding path 13, and a tray lifting device 51 that moves the tray up and down.

The scraping roller lifting device 50 may be, for example, a device that moves the supporting table 32 up and down and, for example, the supporting table 32 may be moved up and down along a rail 60 on the column 33 using an electric motor or a ball screw. For example, the scraping roller lifting device 50 may move the scraping rollers 11 up and down at least from a position 200 mm apart from an entrance position of the drying device 12 to a position 3,500 mm apart from the same entrance position (such distances are measured as a distance to the shaft center of each scraping roller 11). Moreover, the scraping roller lifting device 50 may move the scraping rollers 11 up and down, for example, at least through a distance of 500 mm or more relative to the entrance position of the drying device 12.

The tray lifting device 51 may be, for example, a lifter, which is extendable with a supply of electricity so as to be able move the tray 10 up and down. For example, the tray lifting device 51 may move the tray 10 up and down at least from a position 250 mm apart from the position of the shaft center of each scraping roller 11 to a position 2,000 mm apart from the same position of the shaft center. It should be noted that the reference position of the tray 10 in the above configuration is a position of an inner base surface of the tray 10. Moreover, the tray lifting device 51 may move the tray 10 up and down, for example, at least through a distance of 250 mm or more relative to the shaft center position of the scraping roller 11.

The prepreg manufacturing apparatus 1 further has an adjustment mechanism for adjusting the distance between the impregnation roller 14 and the scraping rollers 11. As shown in, for example, FIG. 2, the impregnation roller 14 is supported by a frame 81 which acts as a connection member attached to an attachment part 80 provided at the supporting mechanism 31 of the scraping rollers 11. The frame 81 is detachable relative to the impregnation roller 14 and the attachment part 80, and a plurality of frames each having a different length is prepared so that the frame 81 can be selected from among those frames. Accordingly, by selecting a particular frame to exchange the frame 81, the distance between the impregnation roller 14 and the scraping rollers 11 can be adjusted. As such frame 81, for example, at least four frames may be prepared, of which the shortest one adjusts the distance between the impregnation roller 14 (the position of the shaft center) and the scraping rollers 11 (the position of the shaft center) to be 200 mm and the remaining frames adjust the same distance to increase by 100 mm increments, and the distance between the impregnation roller 14 and the scraping rollers 11 may be adjusted, for example, between 200 mm and 1,800 mm.

Next, the method for manufacturing prepreg by using the prepreg manufacturing apparatus 1 having the above-described configuration will be described below.

At first, on the base material feeding path 13 shown in FIG. 1, the distance D1 from the liquid surface of the resin varnish H in the tray 10 to the scraping rollers 11 and the distance D2 from the scraping rollers 11 to the drying device 12 are adjusted according to the type of the resin varnish H, and the base material A is then fed along the base material feeding path 13 at a predetermined speed. For example, the feeding speed is preferably 0.5 m/min to 30 m/min, and more preferably 1.0 m/min to 20 m/min. In the present embodiment, the liquid surface of the resin varnish H in the tray 10, the shaft center of the scraping roller 11, and the entrance position of the drying device 12 are regarded as the reference positions that serve as end points when determining the distances D1 and D2.

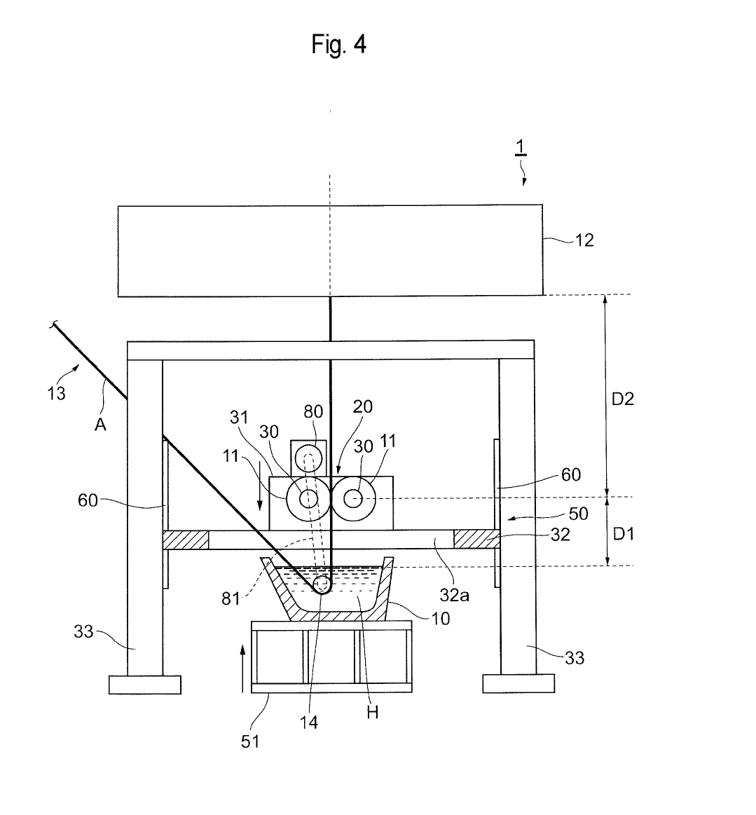

For example, when the resin varnish H used is in a type that is likely to cause unevenness due to dripping; for example, one that contains a relatively large amount of filler, the distance D1 between the resin varnish H in the tray 10 and the scraping rollers 11 is adjusted to a relatively short distance. In this adjustment, as shown in FIG. 4, the distance D1 may be adjusted by moving the scraping rollers 11 down by the scraping roller lifting device 50, by moving the tray 10 up by the tray lifting device 51, or by doing both. Since this adjustment leads to a decrease in the time that is taken from the immersion of the base material A in the resin varnish H to the removal of the excess resin varnish H with the scraping rollers 11, it is possible to suppress the degradation in appearance of the prepreg due to dripping of the resin varnish H that has adhered to the base material A within the tray 10.

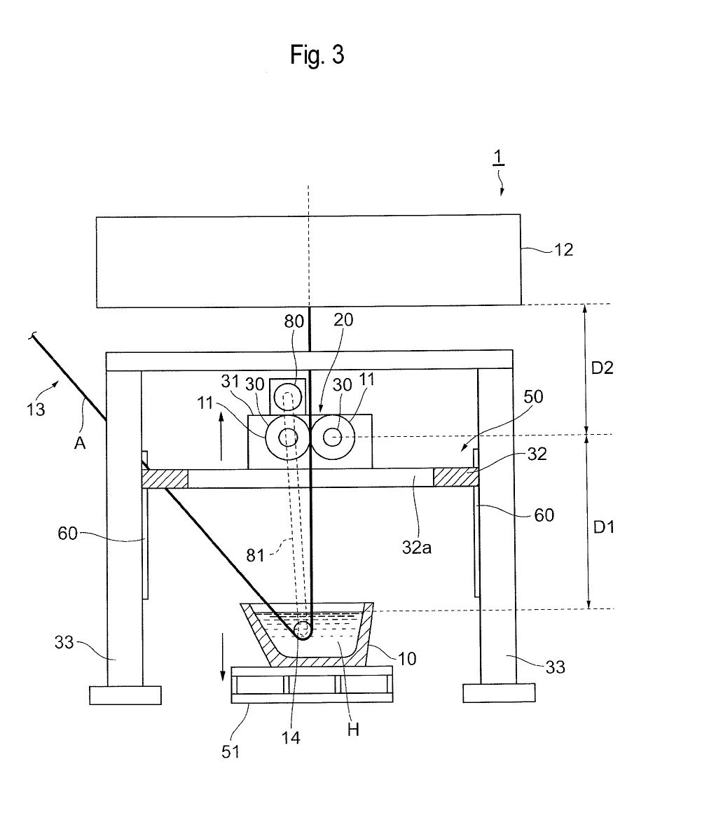

On the other hand, when the resin varnish H used is in a type that does not spread easily, e.g., one having high viscosity, the distance D1 between the resin varnish H in the tray 10 and the scraping rollers 11 is adjusted to a predetermined long distance. In this adjustment, as shown in FIG. 3, the distance D1 may be adjusted by moving the scraping rollers 11 up by the scraping roller lifting device 50, by moving the tray 10 down by the tray lifting device 51, or by doing both. Since this adjustment leads to an increase in the time that is taken from the immersion of the base material A in the resin varnish H to the removal of the excess resin varnish H with the scraping rollers 11, the resin varnish H that has adhered to the base material A within the tray 10 drips moderately and spreads evenly, so that the resulting prepreg has good appearance.

Further, the distance between the impregnation roller 14 and the scraping rollers 11 is also adjusted along with the adjustment of the distance D1 between the resin varnish H in the tray 10 and the scraping rollers 11. For example, the distance between the impregnation roller 14 and the scraping rollers 11 may be adjusted by selecting a frame having an appropriate length from among a plurality of frames 81 having different lengths to thereby exchange the frame.

If the distance D2 between the scraping rollers 11 and the drying device 12 is too short, a solvent contained in the resin varnish H is not sufficiently evaporated between the scraping rollers 11 and the drying device 12, but, rather, it is evaporated abruptly in the drying device 12, and this may leave foaming marks on the surface and degrade the appearance of the prepreg. On the other hand, if the distance D2 between the scraping rollers 11 and the drying device 12 is too long, the resin varnish H may drip excessively and thereby cause degradation in the appearance of the prepreg. Accordingly, the distance D2 between the scraping rollers 11 and the drying device 12 is also adjusted to a predetermined appropriate distance. Such adjustment is performed by moving the scraping rollers 11 and the tray 10 up and down. As a result, the resulting prepreg has good appearance. The distance D2 may be determined according to the type of the resin varnish H, and, for example, it is preferably between 200 mm and 3,500 mm, and more preferably between 250 mm and 3,000 mm.

According to the present embodiment, since the prepreg manufacturing apparatus 1 is configured to be able to adjust the distance D1 from the liquid surface of the resin varnish H in the tray 10 to the scraping rollers 11 on the base material feeding path 13 and the distance D2 from the scraping rollers 11 to the drying device 12, the feed time from the liquid surface of the resin varnish H in the tray 10 to the scraping rollers 11 and the feed time from the scraping rollers 11 to the drying device 12 can be appropriately adjusted according to the type of resin varnish H, without the need to change the speed of feeding the base material A. As a result, when prepreg is manufactured using various types of resin varnish H having different properties, it is possible to manufacture prepreg having good appearance and desired properties without decreasing productivity.

Furthermore, in the present embodiment, since the prepreg manufacturing apparatus 1 has the scraping roller lifting device 50 that moves the scraping rollers 11 up and down along the base material feeding path 13 and the tray lifting device 51 that moves the tray 10 up and down, the distance D1 between the liquid surface of the resin varnish H in the tray 10 and the scraping rollers 11 and the distance D2 between the scraping rollers 11 and the drying device 12 can be automatically adjusted in a simple and accurate manner.

Furthermore, in the present embodiment, along with the adjustment of the distance D1 between the resin varnish H in the tray 10 and the scraping rollers 11, the position of the impregnation roller 14 can also be adjusted in a simple manner by exchanging the frame 81. It should be noted that the adjustment of the distance between the impregnation roller 14 and the scraping rollers 11 may be implemented by using an extendable frame 81. Alternatively, the adjustment may be implemented by moving the impregnation roller 14 together with the tray 10, or by providing a separate lifting device for the impregnation roller 14.

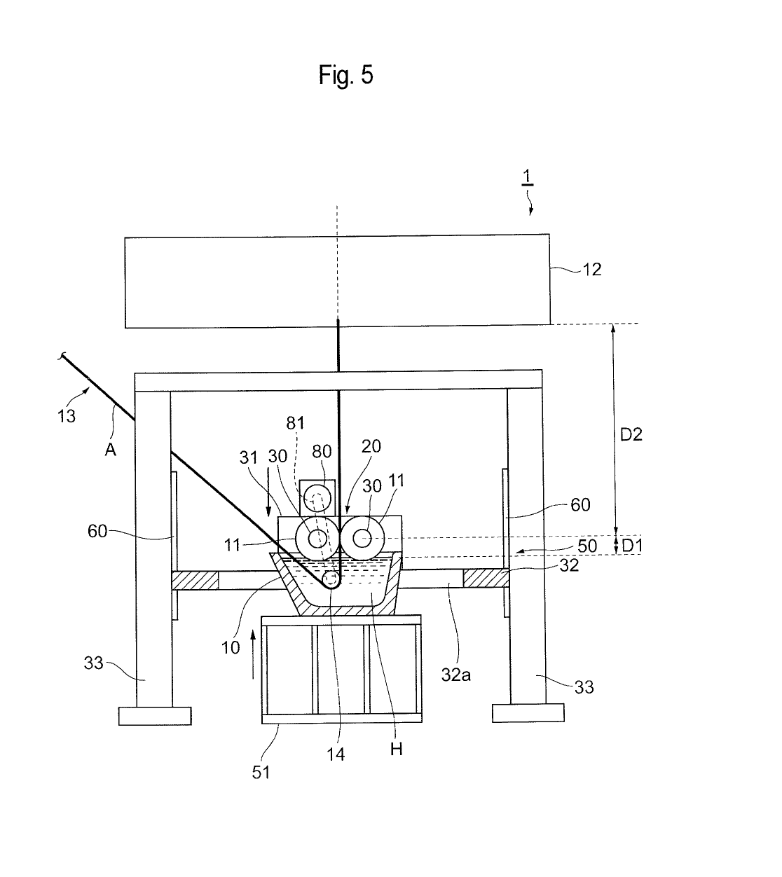

In the above-described embodiment, the scraping roller lifting device 50 may be able to move the scraping rollers 11 to respective positions in contact and not in contact with the resin varnish H in the tray 10. In such a case, depending on the type of resin varnish H, the distance D1 between the liquid surface of the resin varnish H in the tray 10 and the scraping rollers 11 is made extremely short, as shown in FIG. 5, so that the scraping rollers 11 are partly immersed in the resin varnish H in the tray 10. By doing so, excess resin varnish H can be removed immediately after the base material A is immersed in the resin varnish H, so that, for example, dripping can be prevented, thereby achieving good appearance of the prepreg. Moreover, depending on the type of resin varnish H, the scraping rollers 11 may be spaced apart from the liquid surface of the resin varnish H in the tray 10, as shown in FIG. 1, so that the excess resin varnish H can be removed after a desired time has passed from the impregnation of the base material A with the resin varnish H. As a result, it may be possible to, for example, cause dripping in a positive manner, thereby achieving good appearance of the prepreg.

The scraping jig referred to in the above-described embodiment does not have to be a roller, such as the scraping rollers 11, as long as it is able to scrape off excess resin adhered to the surface of the base material A, and the material and shape thereof are not particularly limited. For example, a comma knife may be used.

The resin impregnation method for the base material A is a method for impregnating the base material A, such as a glass cloth, with a resin, and the specific process thereof is not particularly limited. For example, a dipping method in which the base material is continuously dipped in a resin storing tray may be used.

The component composition, etc., of the resin varnish H is not particularly limited. For example, thermosetting resins, such as cyanate ester compounds and epoxy resins, curing agents, curing accelerators, fillers and other additives, etc., may be dissolved or dispersed in a solvent so as to be used as the resin varnish H.

The thermosetting resins used as components of the resin varnish H are not particularly limited, as long as they are thermosetting resins normally used as materials of printed circuit boards. Examples thereof include epoxy resins, cyanate ester compounds, phenolic resins, maleimide compounds and BT resins. These can be used alone or by combining two or more.

For example, phenol phenyl aralkyl novolac-based epoxy resins, phenol biphenyl aralkyl-based epoxy resins, and naphthol aralkyl-based epoxy resins may be used, and, in order to decrease thermal expansion, anthraquinone-based epoxy resins and polyoxynaphthylene-based epoxy resins may also be used. Other examples include bisphenol A-based epoxy resins, bisphenol F-based epoxy resins, phenol novolac-based epoxy resins, cresol novolac-based epoxy resins, bisphenol A novolac-based epoxy resins, trifunctional phenol-based epoxy resins, tetrafunctional phenol-based epoxy resins, naphthalene-based epoxy resins, biphenyl-based epoxy resins, aralkyl novolac-based epoxy resins, alicyclic epoxy resins, polyol-based epoxy resins, glycidyl amines, glycidyl esters, compounds obtained by epoxidizing the double bond of butadiene or the like, and compounds obtained by reaction between a hydroxyl group-containing silicone resins and epichlorohydrin. Of these, phenol phenyl aralkyl novolac-based epoxy resins, phenol biphenyl aralkyl-based epoxy resins, naphthol aralkyl-based epoxy resins, anthraquinone-based epoxy resins, and polyoxynaphthylene-based epoxy resins are particularly preferable in order to improve flame retardancy. These non-halogen epoxy resins can be used alone or by combining two or more as required.

Examples of the cyanate ester compounds include naphthol aralkyl-based cyanate ester compounds, novolac-based cyanate esters, biphenyl aralkyl-based cyanate esters, bis(3,5-dimethyl 4-cyanatophenyl)methane, bis(4-cyanatophenyl)methane, 1,3-dicyanatobenzene, 1,4-dicyanatobenzene, 1,3,5-tricyanatobenzene, 1,3-dicyanatonaphthalene, 1,4-dicyanatonaphthalene, 1,6-dicyanatonaphthalene, 1,8-dicyanatonaphthalene, 2,6-dicyanatonaphthalene, 2,7-dicyanatonaphthalene, 1,3,6-tricyanatonaphthalene, 4, 4′-dicyanatobiphenyl, bis(4-cyanatophenyl)ether, bis(4-cyanatophenyl)thioether, bis(4-cyanatophenyl)sulfone, and 2,2′-bis(4-cyanatophenyl)propane. Of these, naphthol aralkyl-based cyanate ester compounds, novolac-based cyanate esters, and biphenyl aralkyl-based cyanate esters are particularly preferable as they have excellent flame retardancy and high curability and the cured product thereof has a low thermal expansion coefficient.

Examples of the phenolic resins include, but are not particularly limited to, cresol novolac-based phenolic resins, phenol novolac resins, alkyl phenol novolac resins, bisphenol A-based novolac resins, dicyclopentadiene-based phenolic resins, Xylok-based phenolic resins, terpene-modified phenolic resins, polyvinyl phenols, naphthol aralkyl-based phenolic resins, biphenyl aralkyl-based phenolic resins, naphthalene-based phenolic resins, and aminotriazine novolac-based phenolic resins. These can be used alone or by combining two or more, as required, depending on the intended purpose. Of these, cresol novolac-based phenolic resins, aminotriazine novolac-based phenolic resins, naphthalene-based phenolic resins, naphthol aralkyl-based phenolic resins, and biphenyl aralkyl-based phenolic resins are preferable from the viewpoints of water absorbance and heat resistance, and cresol novolac-based phenolic compounds, naphthol aralkyl-based phenolic resins and biphenyl aralkyl-based phenolic resins are particularly preferable.

The maleimide compounds are not particularly limited, as long as they are, for example, compounds having one or more maleimide groups in one molecule thereof. Specific examples thereof include N-phenylmaleimide, N-hydroxyphenylmaleimide, bis(4-maleimidophenyl)methane, 2,2-bis{4-(4-maleimidophenoxy)-phenyl}propane, bis(3,5-dimethyl-4-maleimidophenyl)methane, bis(3-ethyl-5-methyl-4-maleimidophenyl)methane, bis(3,5-diethyl-4-maleimidophenyl)methane, polyphenylmethane maleimide compounds, prepolymers of such maleimide compounds, and prepolymers of maleimide compounds and amine compounds, and they can be used alone or by combining two or more as required. Of these, bis(4-maleimidophenyl)methane, 2,2-bis{4-(4-maleimidophenoxy)-phenyl}propane, bis(3-ethyl-5-methyl-4-maleimidophenyl)methane, and polyphenylmethane maleimide are preferable.

The BT resins used in the present invention are prepolymers obtained by heating and mixing a cyanate ester compound and a maleimide compound in the absence of a solvent or after dissolving them in an organic solvent, such as methyl ethyl ketone, N-methyl pyrrolidone, dimethyl formamide, dimethyl acetamide, toluene, or xylene.

Examples of the inorganic fillers used in the present invention include silica, alumina, isinglass, mica, silicates, barium sulfate, magnesium hydroxide, and titanium oxide, of which silica and alumina are preferable, and silica, such as amorphous silica, fused silica, crystalline silica, synthetic silica, and hollow silica, is particularly preferable. Such silica is preferably spherical. These may be used alone or in combination of two or more. From the viewpoint of lowering the thermal expansion coefficient, fused silica is preferably used.

The upper limit of the average particle size of the inorganic filler is preferably 5 μm or less, more preferably 3 μm or less, and particularly preferably 1 μm or less, from the viewpoint of improving insulation reliability. On the other hand, the lower limit of the average particle size of the inorganic filler is preferably 0.01 μm or more, more preferably 0.05 μm or more, and still more preferably 0.1 μm or more, from the viewpoint of improving dispersibility. In particular, from the viewpoint of enhancing the impregnation of the sheet-like fibrous base material with the resin varnish and obtaining a cured product having a low linear thermal expansion coefficient, it is preferable to use an inorganic filler having an average particle size of 0.01 to 0.3 μm.

The average particle size of the inorganic filler can be determined by a laser diffraction/scattering method based on the Mie scattering theory. Specifically, the average particle size can be determined by calculating a particle size distribution of the inorganic filler on a volumetric basis using a laser diffraction particle size distribution measurement apparatus and taking the median diameter in the distribution as an average particle size. As a measurement sample, a dispersion prepared by dispersing the inorganic filler in water by ultrasonic waves can be preferably used. As the laser diffraction particle size distribution measurement apparatus, for example, LA-500 made by Horiba, Ltd. can be used.

The base material A used in the present invention is not particularly limited, and one type or two or more types selected from glass fibers, organic fibers, non-woven glass fabrics and non-woven organic fabrics may be used. Of these, sheet-like fibrous base materials, such as glass fibers, non-woven aramid fabrics, and non-woven liquid crystal polymer fabrics, are preferable, glass fibers are more preferable, and glass cloth is still more preferable, from the viewpoint of lowering the linear thermal expansion coefficient of the prepreg. For the glass fibers, E glass fibers, T glass fibers, and Q glass fibers are preferable, and T glass fibers and Q glass fibers are more preferable, from the viewpoint of being able to decrease the linear thermal expansion coefficient. The Q glass fibers mean glass fibers in which the content of silicon dioxide is 90% or more. The thickness of such sheet-like fibrous base material is preferably 200 μm or less, more preferably 150 μm or less, and particularly preferably 100 μm or less, from the viewpoint of making the prepreg thinner. On the other hand, the thickness of the sheet-like fibrous base material is preferably 1 μm or more, more preferably 10 μm or more, and particularly preferably 20 μm or more, from the viewpoint of improving handleability.

The thickness of the prepreg is preferably 20 μm or more, more preferably 25 μm or more, and still more preferably 30 μm or more, from the viewpoint of ensuring desired rigidity as a prepreg. On the other hand, the thickness of the prepreg is preferably 250 μm or less, more preferably 150 μm or less, and still more preferably 100 μm or less, from the viewpoint of making metal-clad laminates thinner. The thickness of the prepreg can be controlled easily by adjusting the amount of curable resin composition used for impregnation.

The configurations of the roller supporting device 20, roller driving device 21, scraping roller lifting device 50, tray lifting device 51, etc., described in the above embodiment are not limited to those described above, and they may have different configurations. Furthermore, although the above-described embodiment is configured such that the respective positions of the tray 10 and the scraping rollers 11 are changeable in order to adjust the distance D1 from the liquid surface of the resin varnish H in the tray 10 to the scraping rollers 11 and the distance D2 from the scraping rollers 11 to the drying device 12, the position of the drying device 12 on the base material feeding path 13 may be configured to be adjustable. In such case, the prepreg manufacturing apparatus 1 may be provided with a lifting device for moving the drying device 12 up and down. Moreover, in the above-described embodiment, both the distance D1 between the resin varnish H in the tray 10 and the scraping rollers 11 and the distance D2 between the scraping rollers 11 and the drying device 12 are adjusted according to the type of resin varnish H, but adjustment may be made for either one of such distances.

### INDUSTRIAL APPLICABILITY

In the manufacture of prepreg using various types of resin varnish having different properties, the present invention is effective for manufacturing prepreg having good appearance and desired properties without decreasing productivity.

### REFERENCE SIGNS LIST

1 Prepreg manufacturing apparatus
10 Tray
11 Scraping roller
12 Drying device
13 Base material feeding path
14 Impregnation roller
20 Roller supporting device
21 Roller driving device
32 Supporting table
50 Scraping roller lifting device
51 Tray lifting device
81 Frame
A Base material
D1, D2 Distance
H Resin varnish

1. An apparatus for manufacturing a prepreg, wherein, in a base material feeding path, the base material is immersed in resin varnish in a tray, excess resin varnish on the base material is scraped off using a scraping jig provided above the tray, and the base material is then dried with a drying device, and wherein the prepreg manufacturing apparatus is configured such that respective distances on the base material feeding path from a liquid surface of the resin varnish in the tray to the scraping jig and from the scraping jig to the drying device are adjustable.

2. The prepreg manufacturing apparatus according to claim 1, comprising:
a scraping jig lifting device that moves the scraping jig up and down along the base material feeding path; and
a tray lifting device that moves the tray up and down.

3. The prepreg manufacturing apparatus according to claim 2, further comprising an adjustment mechanism that adjusts a distance between the scraping jig and an impregnation roller that turns up the base material in the resin varnish in the tray.

4. The prepreg manufacturing apparatus according to claim 3, wherein:
the impregnation roller is linked with a supporting mechanism of the scraping jig via a connection member so as to be moveable together with the scraping jig; and
a length of the connection member is changeable.

5. The prepreg manufacturing apparatus according to claim 4, wherein the connection member is selectable from among a plurality of connection members having different lengths.

6. The prepreg manufacturing apparatus according to claim 2, wherein the scraping jig lifting device is able to move the scraping jig to respective positions in contact and not in contact with the resin varnish in the tray.

7. A method for manufacturing a prepreg, wherein, in a base material feeding path, the base material is immersed in resin varnish in a tray, excess resin varnish on the base material is scraped off using a scraping jig provided above the tray, and the base material is then dried with a drying device, the method comprising:
a step of adjusting at least one of a distance from a liquid surface of the resin varnish in the tray to the scraping jig on the base material feeding path or a distance from the scraping jig to the drying device according to a type of the resin varnish on the base material feeding path.

8. The prepreg manufacturing method according to claim 7, wherein the step includes at least one of a step of moving the scraping jig up and down or a step of moving the tray up and down.

9. The prepreg manufacturing method according to claim 8, further comprising a step of adjusting a distance between the scraping jig and an impregnation roller, the impregnation roller turning up the base material in the resin varnish in the tray.

10. The prepreg manufacturing method according to claim 8, wherein the step of moving the scraping jig up and down includes a step of moving the scraping jig to a position in contact with the resin varnish in the tray.
